(19) United States
(12) Patent Application Publication
(10) Pub. No.: US 2025/0006864 A1
(43) Pub. Date: Jan. 2, 2025

(54) SEMICONDUCTOR DEVICE

(71) Applicant: EPISTAR CORPORATION, Hsinchu (TW)

(72) Inventors: Yi-Chieh LIN, Hsinchu (TW); Shih-Chang LEE, Hsinchu (TW); Wei-Chu LIAO, Hsinchu (TW); Mei-Chun LIU, Hsinchu (TW); Hui-Ching FENG, Hsinchu (TW); Zhen-Kai KAO, Hsinchu (TW); Yih-Hua RENN, Hsinchu (TW); Min-Hsun HSIEH, Hsinchu (TW)

(21) Appl. No.: 18/756,777

(22) Filed: Jun. 27, 2024

(30) Foreign Application Priority Data
Jun. 29, 2023 (TW) 112124369

(51) Int. Cl. H01L 33/30; H01L 33/38

(52) U.S. Cl. CPC H01L 33/30; H01L 33/38

(57) ABSTRACT

A semiconductor device is provided, which includes an epitaxial structure, a first contact electrode and a second contact electrode. The epitaxial structure includes a first semiconductor structure, a second semiconductor structure and an active region. The first semiconductor structure includes a first semiconductor contact layer. The second semiconductor structure includes a second semiconductor contact layer. The active region is located between the first semiconductor structure and the second semiconductor structure. The first contact electrode is located on the second semiconductor contact layer and directly contacts the first semiconductor contact layer. The second contact electrode is located on the second semiconductor contact layer and directly contacts the second semiconductor contact layer. The first semiconductor contact layer has a conductivity type of n-type and includes a first group III-V semiconductor material. The second semiconductor contact layer has a conductivity type of p-type and includes a second group III-V semiconductor material.

### CROSS REFERENCE TO RELATED APPLICATIONS

This application claims the right of priority based on TW application No. 112124369, filed on Jun. 29, 2023, which is incorporated by reference herein in its entirety.

### FIELD OF DISCLOSURE

The present disclosure relates to a semiconductor device, in particular, to a semiconductor optoelectronic device.

### BACKGROUND OF THE DISCLOSURE

Nowadays, semiconductor devices are used in a wide range of applications, and research on semiconductor materials and related products continues. For example, group III-V semiconductor materials including group III and group V elements may be applied in various optoelectronic semiconductor devices, such as light-emitting diodes, laser diodes, photodetectors or solar cells, or may be used in power devices such as switching devices or rectifiers. The optoelectronic semiconductor devices may be applied in lighting, medical, display, communication, sensing, power supply system and other fields. As one of the semiconductor light-emitting devices, under an action of an external electric field, a p-type semiconductor structure in the light-emitting diode can provide holes, and an n-type semiconductor structure in the light-emitting diode can provide electrons, and the holes and electrons can recombine and emit light. Since the light-emitting diode may have advantages of low power consumption, fast response speed, small size, and long operating lifetime, they are widely used.

### SUMMARY OF THE DISCLOSURE

The present disclosure provides a semiconductor device. The semiconductor device includes an epitaxial structure, a first contact electrode and a second contact electrode. The epitaxial structure includes a first semiconductor structure, a second semiconductor structure and an active region. The first semiconductor structure includes a first semiconductor contact layer. The second semiconductor structure includes a second semiconductor contact layer. The active region is located between the first semiconductor structure and the second semiconductor structure. The first contact electrode is located on the second semiconductor contact layer and directly contacts the first semiconductor contact layer. The second contact electrode is located on the second semiconductor contact layer and directly contacts the second semiconductor contact layer. The first semiconductor contact layer has a conductivity type of n-type and includes a first group III-V semiconductor material. The second semiconductor contact layer has a conductivity type of p-type and includes a second group III-V semiconductor material. The second group III-V semiconductor material is an indium-containing phosphide.

The present disclosure provides a semiconductor device. The semiconductor device includes an epitaxial structure, a first contact electrode and a second contact electrode. The epitaxial structure includes a first semiconductor structure, a second semiconductor structure and an active region. The first semiconductor structure includes a first semiconductor contact layer. The second semiconductor structure includes a second semiconductor contact layer. The active region is located between the first semiconductor structure and the second semiconductor structure. The first contact electrode is located on the first semiconductor contact layer and directly contacts the first semiconductor contact layer. The second contact electrode is located on the first semiconductor contact layer and directly contacts the second semiconductor contact layer. The first semiconductor contact layer has a conductivity type of n-type and includes a first group III-V semiconductor material. The second semiconductor contact layer has a conductivity type of p-type and includes a second group III-V semiconductor material. The first group III-V semiconductor material is an indium-containing phosphide and is a ternary group III-V compound semiconductor.

### BRIEF DESCRIPTION OF THE DRAWINGS

FIG. 1A shows a schematic sectional view of an epitaxial structure and a base in accordance with an embodiment of the present disclosure.

FIG. 1B shows a schematic sectional view of a first semiconductor contact layer in accordance with an embodiment of the present disclosure.

FIG. 2A shows a schematic sectional view of a semiconductor device in accordance with an embodiment of the present disclosure.

FIG. 2B shows a schematic sectional view of a semiconductor device in accordance with an embodiment of the present disclosure.

FIG. 2C shows a schematic sectional view of a semiconductor device in accordance with an embodiment of the present disclosure.

FIG. 3A shows a schematic top view of a semiconductor device in accordance with an embodiment of the present disclosure.

FIG. 3B shows a schematic sectional view of the semiconductor device of FIG. 3A along A-A′ line.

FIG. 4A to FIG. 4F show schematic views of a method for producing a semiconductor component in accordance with an embodiment of the present disclosure.

FIG. 4G shows a schematic top view of a semiconductor component in accordance with an embodiment of the present disclosure.

FIG. 5A to FIG. 5F show schematic views of a method for producing a semiconductor component in accordance with an embodiment of the present disclosure.

FIG. 6 shows a schematic top view of a semiconductor component in accordance with an embodiment of the present disclosure.

### DETAILED DESCRIPTION OF THE DISCLOSURE

The following embodiments will be described with accompany drawings to disclose the concept of the present disclosure. In the drawings or description, same or similar portions are indicated with same or similar numerals. Furthermore, a shape or a size of a member in the drawings may be enlarged or reduced. Particularly, it should be noted that a member which is not illustrated or described in drawings or description may be in a form that is known by a person skilled in the art.

The semiconductor device of the present disclosure is, for example, a light-emitting device (such as a light-emitting diode or a laser diode), a light absorbing device (such as a photo-detector) or a non-illumination device. The qualitative or quantitative analysis of the composition and/or dopant contained in each layer of the semiconductor device of the present disclosure may be conducted by any suitable method, for example, a secondary ion mass spectrometer (SIMS). A thickness of each layer may be obtained by any suitable method, such as a transmission electron microscopy (TEM) or a scanning electron microscope (SEM).

Those with ordinary knowledge in the art should understand that other member(s) may be added on the basis of each embodiment described below. For example, if not otherwise specified, a description similar to “a first layer/structure is on or under a second layer/structure” may include an embodiment in which the first layer/structure is in direct contact with (or physically/directly contacts) the second layer/structure, and may also include an embodiment in which another structure is provided between the first layer/structure and the second layer/structure, such that the first layer/structure and the second layer/structure do not directly contact each other. Furthermore, it should be realized that a positional relationship of a layer/structure may be altered when being observed in different orientations.

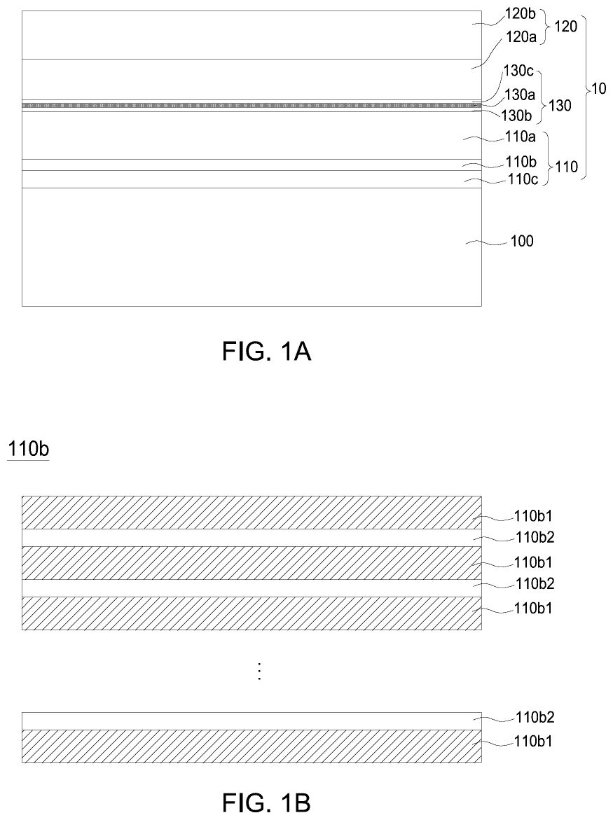

FIG. 1A shows a schematic sectional view of an epitaxial structure 10 and a base 100 in accordance with an embodiment of the present disclosure. As shown in FIG. 1A, the epitaxial structure 10 includes a first semiconductor structure 110, a second semiconductor structure 120 and an active region 130. The active region 130 is located between the first semiconductor structure 110 and the second semiconductor structure 120. The first semiconductor structure 110 and the second semiconductor structure 120 are respectively located on two sides of the active region 130 and adjacent to the active region 130. The epitaxial structure 10 can be formed on the base 100. As shown in FIG. 1A, the base 100 is located under the first semiconductor structure 110, the second semiconductor structure 120 and the active region 130. In this embodiment, the base 100 is a growth substrate for epitaxial growth, such as a gallium arsenide (GaAs) substrate.

The first semiconductor structure 110, the second semiconductor structure 120, and the active region 130 may respectively include a group III-V semiconductor material. The group III-V semiconductor material may include an element or elements containing aluminum (Al), gallium (Ga), arsenic (As), phosphorus (P), nitrogen (N) or indium (In). In an embodiment, the first semiconductor structure 110, the active region 130, and the second semiconductor structure 120 may not include the element N. Specifically, the group III-V semiconductor material may be a binary group III-V compound semiconductor (such as GaAs, GaP or GaN), a ternary group III-V compound semiconductor (such as InGaAs, AlGaAs, InGaP, AlInP, InGaN or AlGaN) or a quaternary group III-V compound semiconductor (such as AlGaInAs, AlGaInP, AlInGaN, InGaAsP, InGaNAs or AlGaAsP). In accordance with an embodiment, the total thickness of the epitaxial structure 10 can be in the range of 1 μm to 5 μm for further reducing the thickness of the semiconductor device, which may help to miniaturize the semiconductor device.

The first semiconductor structure 110 and the second semiconductor structure 120 may have different conductivity types to respectively provide electrons and holes. For example, the first semiconductor structure 110 is n-type and the second semiconductor structure 120 is p-type. The electrons and holes can combine in the active region 130 to emit light of a specific wavelength. The light may include visible light or invisible light. The conductivity types of the first semiconductor structure 110 and the second semiconductor structure 120 can be adjusted by adding different dopants. The dopants may include elements from group II, group IV or group VI in the periodic table of elements, such as magnesium (Mg), zinc (Zn), carbon (C), silicon (Si) or tellurium (Te).

The first semiconductor structure 110 and the second semiconductor structure 120 may be single-layer or multi-layer structures. In this embodiment, the first semiconductor structure 110 may include a first cladding layer 110a and a first semiconductor contact layer 110b. In this embodiment, the first semiconductor contact layer 110b is n-type and the first semiconductor contact layer 110b includes a first group III-V semiconductor material. The second semiconductor structure 120 may include a second cladding layer 120a and a second semiconductor contact layer 120b. In this embodiment, the conductivity type of the second semiconductor contact layer 120b is p-type and the second semiconductor contact layer 120b includes a second group III-V semiconductor material. The first group III-V semiconductor material is different from the second group III-V semiconductor material. In accordance with an embodiment, one of the first group III-V semiconductor material and the second group III-V semiconductor material may be a ternary group III-V compound semiconductor, and the other may be a binary group III-V compound semiconductor. In accordance with an embodiment, one of the first group III-V semiconductor material and the second group III-V semiconductor material may be an indium-containing phosphide, and the other may not be an indium-containing phosphide. By including different group III-V semiconductor materials in the first semiconductor contact layer 110b and the second semiconductor contact layer 120b, the first semiconductor contact layer 110b in the epitaxial structure 10 and the second semiconductor contact layer 120b can respectively provide appropriate contact characteristics.

In an embodiment, in the first semiconductor contact layer 110b or the second semiconductor contact layer 120b, a side away from the active region 130 has a higher dopant concentration than a side closer to the active region 130, such that better contact characteristics can be provided. For example, the dopant concentration may gradually increase from the side close to the active region 130 to the side away from the active region 130. In an embodiment, the dopant concentration on the side away from the active region 130 may be 10 times or more, such as 10 to 100 times, the dopant concentration on the side close to the active region 130. In accordance with an embodiment, the dopant in the second semiconductor contact layer 120b may include magnesium (Mg), zinc (Zn), or carbon (C), and the dopant in the first semiconductor contact layer 110b may include silicon (Si) or tellurium (Te).

In accordance with an embodiment, the first group III-V semiconductor material can be a binary group III-V compound semiconductor, such as gallium arsenide (GaAs), and the second group III-V semiconductor material can be a ternary group III-V compound semiconductor. The second group III-V semiconductor material can be an indium-containing phosphide such as InₓGa₁₋ₓP, and 0<x<1. In accordance with another embodiment, the first group III-V semiconductor material can be a ternary group III-V compound semiconductor, and the first group III-V semiconductor material can be an indium-containing phosphide such as Al_{y}In_{1-y}P, and 0<y<1, and the second group III-V semiconductor material may be a binary group III-V compound semiconductor such as gallium phosphide (GaP). Since the n-type first semiconductor contact layer 110b and the p-type second semiconductor contact layer 120b respectively includes the materials mentioned above, it may help to further reduce the resistance between the semiconductor contact layer(s) and a metal when forming a metal-semiconductor interface.

In accordance with an embodiment, when the second group III-V semiconductor material includes the element indium, an indium content percentage in the second group III-V semiconductor material can be in a range of 1% to 30%, thereby the second semiconductor contact layer may have better resistance performance. The indium content percentage can be defined as a content percentage of indium in all group III elements in the first group III-V semiconductor material. The indium content percentage can be obtained, for example, by using an energy dispersive spectrometer (EDX) to analyze the second semiconductor contact layer 120b, and calculating the indium content percentage (In %) of the second group III-V semiconductor material in the second semiconductor contact layer 120b from the analysis results. For example, when the second group III-V semiconductor material is InₓGa₁₋ₓP, the atomic percentages (at %) of In, Ga and P can be obtained by EDX measurements, and x can be calculated. Specifically, x can be obtained by dividing the atomic percentage (at %) of indium (In) by the atomic percentage (at %) of the group V element (i.e., phosphorus (P)) in the second semiconductor contact layer 120b. Here, the indium content percentage (In %) can be defined as x*100%. According to some embodiments, when the second group III-V semiconductor material is InₓGa₁₋ₓP, and x is in a range of 0.05 to 0.3 (that is, the indium content percentage in the second group III-V semiconductor material is in a range of 5% to 30%). The second group III-V semiconductor material can have a lower bandgap than gallium phosphide (GaP), thus may help to further reduce resistance.

The first semiconductor contact layer 110b may be the layer with the smallest or the largest thickness in the first semiconductor structure 110, and the second semiconductor contact layer 120b may be the layer with the smallest or largest thickness in the second semiconductor structure 120. As shown in FIG. 1A, a thickness of the first semiconductor contact layer 110b may be smaller than a thickness of the second semiconductor contact layer 120b. In another embodiment, the thickness of the first semiconductor contact layer 110b may be greater than or equal to the thickness of the second semiconductor contact layer 120b. According to some embodiments, the thickness of the first semiconductor contact layer 110b and the thickness of the second semiconductor contact layer 120b may be respectively in a range of 300 Å to 30000 Å.

The first semiconductor structure 110 may optionally include an etching stop layer 110c located between the first semiconductor contact layer 110b and the base 100. The first semiconductor structure 110 may optionally include a transition layer (not shown) between the base 100 and the etching stop layer 110c. The material of the transition layer and the etching stop layer 110c may respectively include a binary or ternary group III-V compound semiconductor, such as gallium arsenide (GaAs) or indium gallium phosphide (InGaP).

Specifically, the active region 130 may include a double heterostructure (DH), a double-side double heterostructure (DDH) or multiple quantum wells (MQW) structure. In accordance with an embodiment, when a semiconductor device includes the epitaxial structure 10 and is a light-emitting device, the active region 130 can emit a light when the semiconductor device operates. The light includes visible light or invisible light. The light emitted by the semiconductor device is determined by material composition in the active region 130. For example, when the material of the active region 130 includes InGaP or AlGaInP, the yellow, orange or red light with a peak wavelength of 530 nm to 700 nm can be emitted, and when the material of the active region 130 includes InGaAs, InGaAsP, AlGaAs or AlGaInAs, for example, the infrared light with a peak wavelength of 700 nm to 1700 nm can be emitted.

The active region 130 may include a light-emitting region 130a, a first confinement layer 130b and a second confinement layer 130c. The first confinement layer 130b and the second confinement layer 130c are located on two sides of the light-emitting region 130a. The light-emitting region 130a includes multiple pairs of alternately stacked well layers and barrier layers (not shown). Each of the materials of the well layer and barrier layer may include an element or elements containing aluminum (Al), gallium (Ga), arsenic (As), phosphorus (P) or indium (In). According to some embodiments, the materials of the well layer and barrier layer may include quaternary group III-V semiconductor compounds, such as AlGaInP, InGaAsP or AlGaInAs.

Based on the above, in the epitaxial structure 10 of the embodiment of the present invention, by including afore-mentioned combination of the first group III-V semiconductor material and the second group III-V semiconductor material in the first semiconductor contact layer 110b and the second semiconductor contact layer 120b, the first semiconductor contact layer 110b and the second semiconductor contact layer 120b can respectively provide appropriate contact characteristics.

FIG. 1B shows a schematic sectional view of a first semiconductor contact layer 110b in accordance with an embodiment of the present disclosure. In this embodiment, the first semiconductor contact layer 110b has multiple pairs of alternately stacked first sublayers 110b1 and second sublayers 110b2. In accordance with an embodiment, the first semiconductor contact layer 110b may have 2 to 500 pairs of the first sublayers 110b1 and the second sublayers 110b2 that are alternately stacked. Thicknesses of each first sublayer 110b1 and each second sublayer 110b2 may be the same or different. The first sublayers 110b1 can include the first group III-V semiconductor material, and the second sublayers 110b2 can include a third group III-V semiconductor material different from the first group III-V semiconductor material. The third group III-V semiconductor material may be a ternary group III-V compound semiconductor. In an embodiment, the first group III-V semiconductor material can be an indium-containing phosphide, such as Al_{y}In_{1-y}P, and 0<y<1; the third group III-V semiconductor material can be an indium-containing phosphide, such as In_{z}Ga_{1-z}P, and 0<z<1. In an embodiment, the thickness of each first sublayer 110b1 is greater than the thickness(es) of the adjacent second sublayer(s) 110b2. A ratio of the thickness of each first sublayer 110b1 to the thickness of each second sublayer 110b2 may be in a range of 0.5 to 15, for example, in the range of 1.5 to 5. In accordance with an embodiment, the thickness of each first sublayer 110b1 is, for example, in a range of 30 Å to 300 Å, and the thickness of each second sublayer 110b2 is, for example, in a range of 20 Å to 60 Å. In this embodiment, the first semiconductor contact layer 110b have multiple pairs of the first sublayers 110b1 and the second sublayers 110b2 that are alternately stacked, such that the resistance of the first semiconductor contact layer 110b can be further reduced.

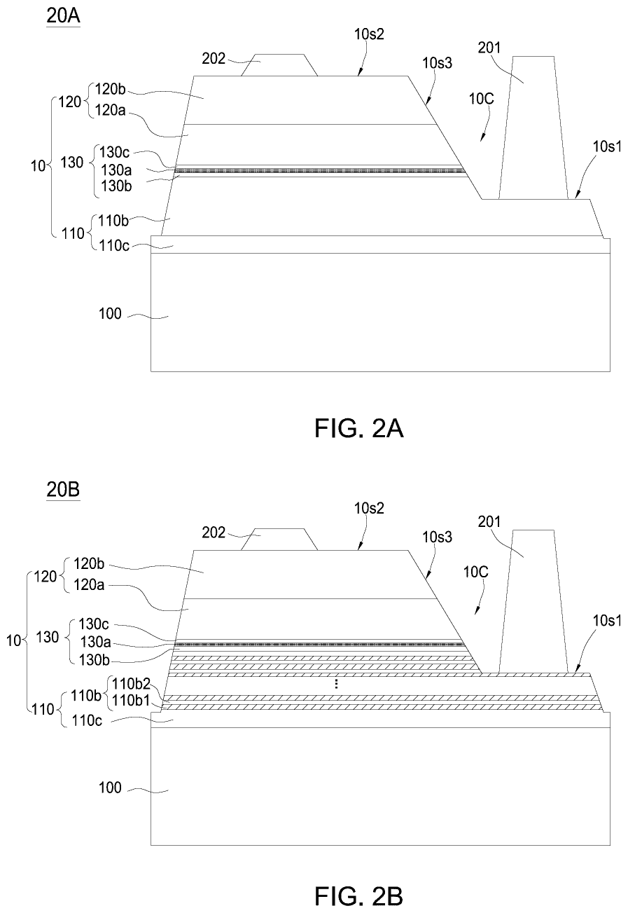

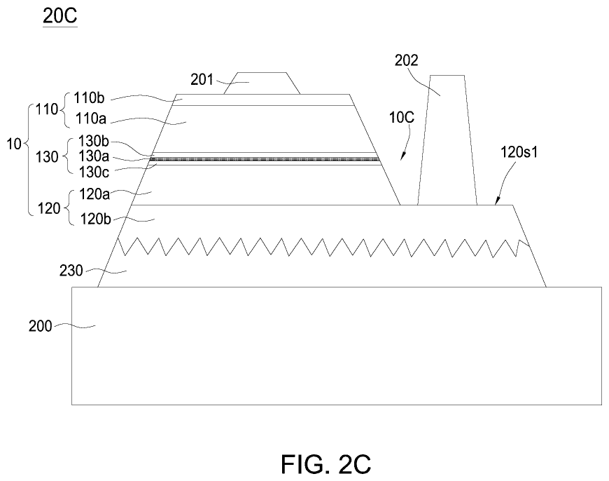

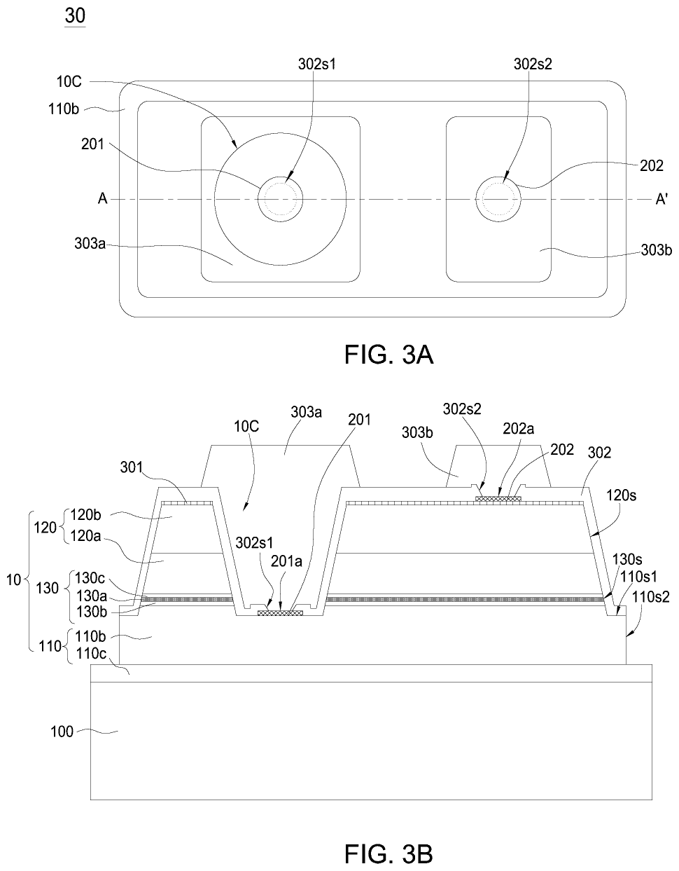

FIG. 2A shows a schematic sectional view of a semiconductor device 20A in accordance with an embodiment of the present disclosure. The semiconductor device 20A includes the epitaxial structure 10, a first contact electrode 201, and a second contact electrode 202. The epitaxial structure 10 includes the first semiconductor structure 110, the second semiconductor structure 120 and the active region 130. The first semiconductor structure 110 includes the first semiconductor contact layer 110b and optionally includes the etching stop layer 110c. The second semiconductor structure 120 includes the second cladding layer 120a and the second semiconductor contact layer 120b. The active region 130 is located between the first semiconductor structure 110 and the second semiconductor structure 120. The first contact electrode 201 is located on the first semiconductor contact layer 110b and directly contacts the first semiconductor contact layer 110b. The second contact electrode 202 is located on the first semiconductor contact layer 110b and directly contacts the second semiconductor contact layer 120b. Semiconductor device 20A may optionally include the base 100. The base 100 is located under the epitaxial structure 10.

As shown in FIG. 2A, the epitaxial structure 10 may have a first surface 10s1, a second surface 10s2 and a side surface 10s3. There is a horizontal height difference between the first surface 10s1 and the second surface 10s2, and the side surface 10s3 connects the first surface 10s1 and the second surface 10s2. In this embodiment, the epitaxial structure 10 has a recess 10C on a side. The recess 10C can be defined by the first surface 10sl and the side surface 10s3. The first contact electrode 201 is formed in the recess 10C (or on the first surface 10s1) and is in direct contact with the first semiconductor contact layer 110b to form an electrical connection. In some embodiments, a top-view shape of the recess 10C may be circular, elliptical, rectangular or other polygonal. In this embodiment, the first semiconductor structure 110 does not include the first cladding layer 110a as shown in FIG. 1A. The first semiconductor contact layer 110b serves as the thickest layer in the first semiconductor structure 110 and can provide carriers (such as electrons), structural support, current diffusion, and contact characteristics needed.

According to some embodiments, materials of the first contact electrode 201 and the second contact electrode 202 may include metal or alloy. The metal may include germanium (Ge), beryllium (Be), zinc (Zn), gold (Au), nickel (Ni) or copper (Cu). The alloy may include two or more of the above metals, such as germanium gold nickel (GeAuNi), beryllium gold (BeAu), germanium gold (GeAu), or zinc gold (ZnAu). The materials of the first contact electrode 201 and the second contact electrode 202 may be different or the same. In accordance with an embodiment, the first contact electrode 201 includes germanium gold (GeAu), and the second contact electrode 202 includes beryllium gold (BeAu).

Specifically, the method for producing the semiconductor device 20A may include the following steps: performing epitaxial growth on the base 100 to form the epitaxial structure 10 (in which the base 100 is a growth substrate (such as gallium arsenide) for epitaxial growth); removing a portion of the epitaxial structure 10 (including a portion of the first semiconductor structure 110, a portion of the second semiconductor structure 120, and a portion of the active region 130) to form the recess 10C so as to expose the first semiconductor structure 110; forming the first contact electrode 201 which is in direct contact with the first semiconductor contact layer 110b in the recess 10C, and forming the second contact electrode 202 which is in direct contact with the second semiconductor contact layer 120b on the second semiconductor contact layer 120b. In an embodiment, the method for producing the semiconductor device 20A may optionally include removing the base 100 after forming the first contact electrode 201 and the second contact electrode 202.

In this embodiment, the first semiconductor contact layer 110b can have multiple functions including providing carriers and forming ohmic contact with the first contact electrode 201, which may further simplify the device structure and producing process, also help to reduce production costs. The detailed descriptions of positions, relative relationships and material of other layers or structures as well as structural variations in this embodiment can be referred to the foregoing embodiments and are not repeatedly described herein.

FIG. 2B shows a schematic sectional view of a semiconductor device 20B in accordance with an embodiment of the present disclosure. The main difference between the semiconductor device 20B and the semiconductor device 20A is that the first semiconductor contact layer 110b of semiconductor device 20B has multiple pairs of the first sublayers 110b1 and the second sublayers 110b2 that are alternately stacked. Regarding the structure, materials and other information of the first sublayers 110b1 and the second sublayers 110b2, the aforementioned description of the embodiment in FIG. 1B can be referred to. In this embodiment, the first contact electrode 201 is in direct contact with one of the first sublayers 110b1 to form an electrical connection. In another embodiment, the first contact electrode 201 may be in direct contact with one of the plurality of second sublayers 110b2 to form an electrical connection.

Specifically, the method for producing the semiconductor device 20B may include the following steps: performing epitaxial growth on the base 100 to form the epitaxial structure 10 (in which the base 100 is a growth substrate, such as gallium arsenide, for epitaxial growth); removing a portion of the epitaxial structure 10 (including a portion of the first semiconductor structure 110, a portion of the second semiconductor structure 120, and a portion of the active region 130) to form the recess 10C so as to expose one of the first sublayers 110b1 (or one of the second sublayers 110b2); forming the first contact electrode 201 which is in direct contact with one of the first sublayers 110b1 (or one of the second sublayer 110b2) in the recess 10C, and forming the second contact electrode 202 which is in direct contact with the second semiconductor contact layer 120b on the second semiconductor contact layer 120b. In an embodiment, the method for producing semiconductor device 20B may optionally include removing the base 100 after forming the first contact electrode 201 and the second contact electrode 202.

In this embodiment, the first semiconductor contact layer 110b have multiple pairs of the first sublayers 110b1 and the second sublayers 110b2 that are alternately stacked, so that the resistance of the first semiconductor contact layer 110b may be further reduced, that may help to improve electrical properties of the device. The detailed descriptions of positions, relative relationships and material of other layers or structures as well as structural variations in this embodiment can be referred to the foregoing embodiments and are not repeatedly described herein.

FIG. 2C shows a schematic sectional view of a semiconductor device 20C in accordance with an embodiment of the present disclosure. The main difference between the semiconductor device 20C and the semiconductor device 20A is that the semiconductor device 20C includes a bonding structure 230 located between a base 200 and the epitaxial structure 10, and the first semiconductor structure 110 does not include the etching stop layer 110c. In this embodiment, the base 200 is a bonding substrate. The bonding substrate may be conductive or electrically insulating, such as a silicon (Si) substrate or a sapphire substrate. Specifically, the material of the base 200 can absorb less light emitted by the active region 130 than the growth substrate, so as to improve the luminous efficiency of the device. The bonding structure 230 can be electrically insulating. In an embodiment, the material of the bonding structure 230 includes a polymer material, such as benzocyclobutene (BCB), epoxy, polyimide, or silicone resin, alumina (Al₂O₃), or silicon oxide (SiO₂).

Specifically, the method for producing the semiconductor device 20C may include the following steps: performing epitaxial growth on a growth substrate (not shown) to form the epitaxial structure 10; bonding the base 200 and the epitaxial structure 10 through the bonding structure 230 which directly contacts the second semiconductor structure 120 and the base 200; removing the growth substrate for epitaxial growth; removing a portion of the epitaxial structure 10 (including a portion of the first semiconductor structure 110, a portion of the second semiconductor structure 120, and a portion of the active region 130) to form the recess 10C to expose a surface 120s1 of the second semiconductor contact layer 120b; and forming the first contact electrode 201 which is in direct contact with the first semiconductor contact layer 110b on the first semiconductor contact layer 110b, and forming the second contact electrode 202 which is in direct contact with the second semiconductor contact layer 120b in the recess 10C. In accordance with an embodiment, before bonding the base 200 and the epitaxial structure 10 through the bonding structure 230, a step of roughening a surface for bonding in the epitaxial structure 10 can be optionally included to make it easier to form a stable bonding structure.

According to some embodiments, when a wavelength range of light emitted by the active region 130 overlaps with a wavelength range of light that may be absorbed by the material of the growth substrate, by transferring the epitaxial structure 10 from the growth substrate to the bonding substrate, and removing the growth substrate, the brightness of the semiconductor device can be improved. The detailed descriptions of positions, relative relationships and material of other layers or structures as well as structural variations in this embodiment can be referred to the foregoing embodiments and are not repeatedly described herein.

FIG. 3A shows a schematic top view of a semiconductor device 30 in accordance with an embodiment of the present disclosure. FIG. 3B shows a schematic sectional view of the semiconductor device 30 of FIG. 3A along A-A′ line.

The semiconductor device 30 includes the base 100 and the epitaxial structure 10 located on the base 100. The epitaxial structure 10 includes the first semiconductor structure 110, the second semiconductor structure 120 and the active region 130. The first semiconductor structure 110 includes the first semiconductor contact layer 110b. The second semiconductor structure 120 includes the second cladding layer 120a and the second semiconductor contact layer 120b. The active region 130 is located between the first semiconductor structure 110 and the second semiconductor structure 120. The first semiconductor structure 110 may optionally include the etching stop layer 110c located between the base 100 and the first semiconductor contact layer 110b. As shown in FIG. 3A and FIG. 3B, the epitaxial structure 10 has the recess 10C. In this embodiment, the recess 10C is located in the epitaxial structure 10. As shown in FIG. 3A, when viewed from above, the outline of the recess 10C is a closed figure, such as a circle. The semiconductor device 30 further includes the first contact electrode 201. The first contact electrode 201 is formed in the recess 10C and is in direct contact with the first semiconductor contact layer 110b to form an electrical connection. The second contact electrode 202 is located on the first semiconductor contact layer 110b and forms an electrical connection with the second semiconductor contact layer 120b. When viewed from above, the first contact electrode 201 and the second contact electrode 202 may have circular, elliptical, rectangular or other polygonal shapes.

The semiconductor device 30 further includes an insulating structure 302 located on the epitaxial structure 10. The insulation structure 302 has a first opening 302s1 and a second opening 302s2 corresponding to the first contact electrode 201 and the second contact electrode 202 respectively. In an embodiment, the insulating structure 302 may cover a portion of the upper surface 201a of the first contact electrode 201 and a portion of the upper surface 202a of the second contact electrode 202. The insulation structure 302 can provide insulation and/or reflection functions, and can isolate external moisture or pollution to prevent the active region 130 in the epitaxial structure 10 from being damaged. The insulating structure 302 may have a single-layer or multi-layer structure, and may include a dielectric material such as oxide, nitride, polymer, or combinations thereof. The oxide may include aluminum oxide (AlOₓ), silicon oxide (SiOₓ), titanium oxide (TiOₓ), niobium pentoxide (Nb₂O₅) or tantalum pentoxide (Ta₂O₅). The nitride can include aluminum nitride (AlN) or silicon nitride (SiNx). The polymer may include polyimide or benzocyclobutane (BCB).

In an embodiment, the insulating structure 302 may further have a reflective function, for example, by including a Distributed Bragg Reflector (DBR) structure. The DBR may include a plurality of first dielectric layers and a plurality of second dielectric layers (not shown) that are alternately stacked, and the first dielectric layers and the second dielectric layers have different refractive indexes. The first dielectric layer and the second dielectric layer may respectively include silicon dioxide (SiO₂), titanium dioxide (TiO₂), or niobium pentoxide (Nb₂O₅). For example, a combination of the first dielectric layer and the second dielectric layer can be SiO₂/TiO₂ or SiO₂/Nb₂O₅. Since the insulation structure 180 has a reflective function, the light emitted by the active region 130 can be mainly emitted from the first semiconductor structure 110 side. In an embodiment, the insulating structure 302 may include a distributed Bragg reflector (DBR). The insulating structure 302 may cover a side surface 120s of the second semiconductor structure 120 and a side surface 130s of the active region 130. In this embodiment, the insulating structure 302 covers a portion of a surface 110s1 of the first semiconductor structure 110 but does not cover a side surface 110s2 of the first semiconductor structure 110.

The semiconductor device 30 may optionally include a conductive oxide layer 301. The conductive oxide layer 301 may be located on the epitaxial structure 10 and may be located between the epitaxial structure 10 and insulating structure 302. As shown in FIG. 3B, the conductive oxide layer 301 located between the epitaxial structure 10 and the second contact electrode 202 can form ohmic contact with the second semiconductor contact layer 120b to provide a better electrical connection. In some embodiments, the conductive oxide layer 301 can also assist in lateral current diffusion and improve current distribution in the device. The material of the conductive oxide layer 301 may include indium tin oxide (ITO), indium oxide (InO), tin oxide (SnO), cadmium tin oxide (CTO), antimony tin oxide (ATO), aluminum zinc oxide (AZO), oxide Zinc tin (ZTO), gallium zinc oxide (GZO), indium tungsten oxide (IWO), zinc oxide (ZnO), indium zinc oxide (IZO) or a combination thereof.

The semiconductor device 30 further includes a first electrode pad 303a and a second electrode pad 303b. The first electrode pad 303a fills the recess 10C and the first opening 302s1 and directly contacts the upper surface 201a of the first contact electrode 201 to form an electrical connection. The second electrode pad 303b fills the second opening 302s2 and directly contacts the upper surface 202a of the second contact electrode 202 to form an electrical connection. The first electrode pad 303a and the second electrode pad 303b may include metal, such as nickel (Ni), titanium (Ti), platinum (Pt), palladium (Pd), silver (Ag), gold (Au), aluminum (Al), tin (Sn), copper (Cu), bismuth (Bi), indium (In) or a combination thereof. In an embodiment, an upper surface of the first electrode pad 303a and an upper surface of the second electrode pad 303b may have approximately the same height. As shown in FIG. 3A, when viewed from above, each of the first electrode pad 303a and the second electrode pad 303b may be a rectangle with rounded corners. In accordance with an embodiment, as shown in FIG. 3A, when viewed from above, a diagonal length of the first semiconductor contact layer 110b can be in a range of greater than 1 μm and less than 50 μm to meet the needs of device miniaturization. A top-view area of the first electrode pad 303a may be greater than, less than, or equal to the top-view area of the second electrode pad 303b. As shown in FIG. 3A, the top-view area of the first electrode pad 303a can be larger than the top-view area of the recess 10C to ensure that the first electrode pad 303a can fill up the recess 10C.

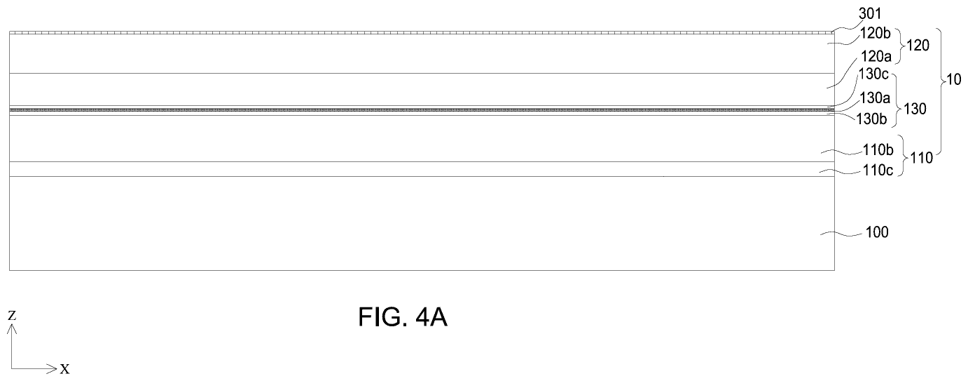

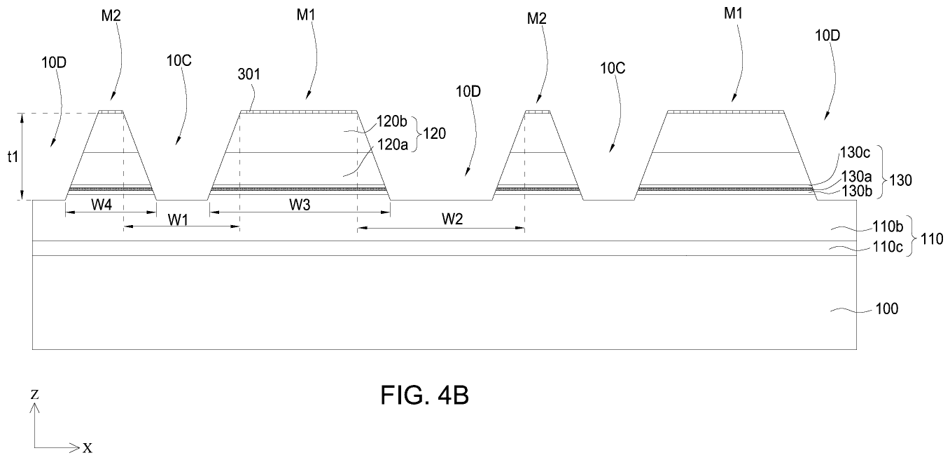

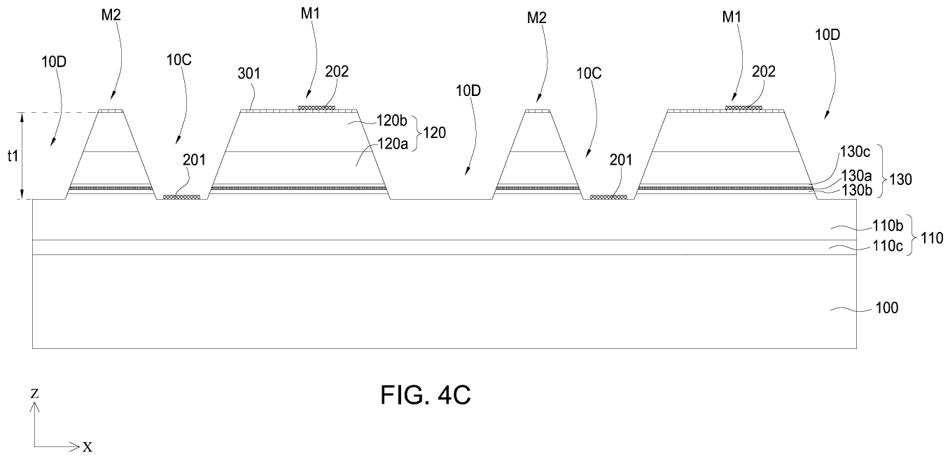

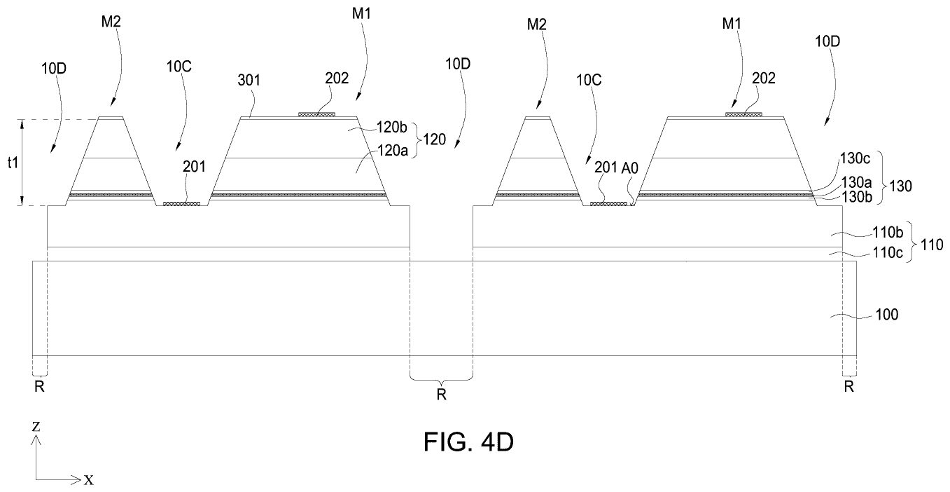

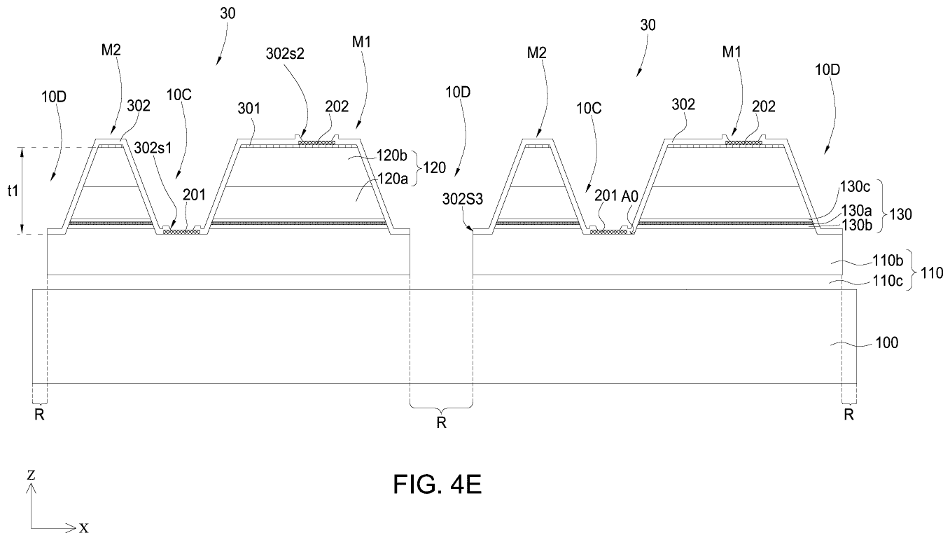

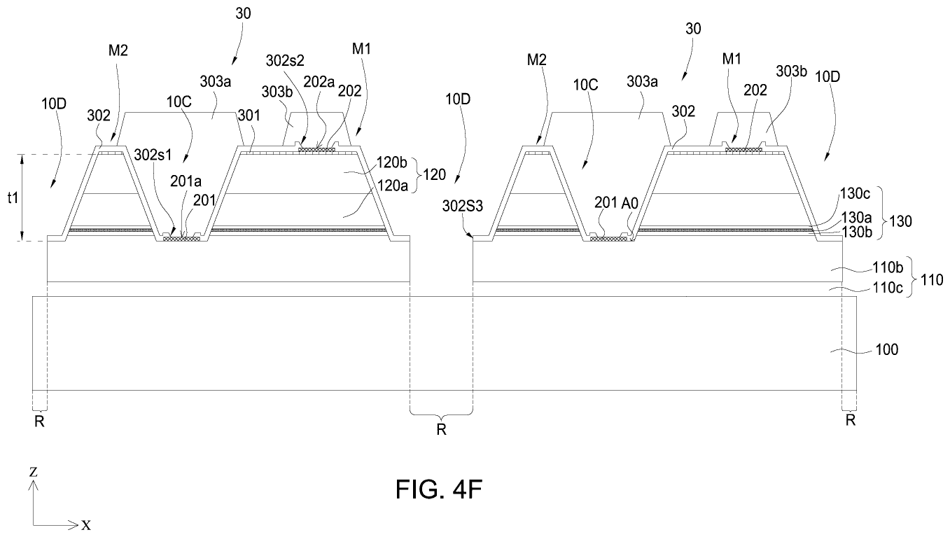

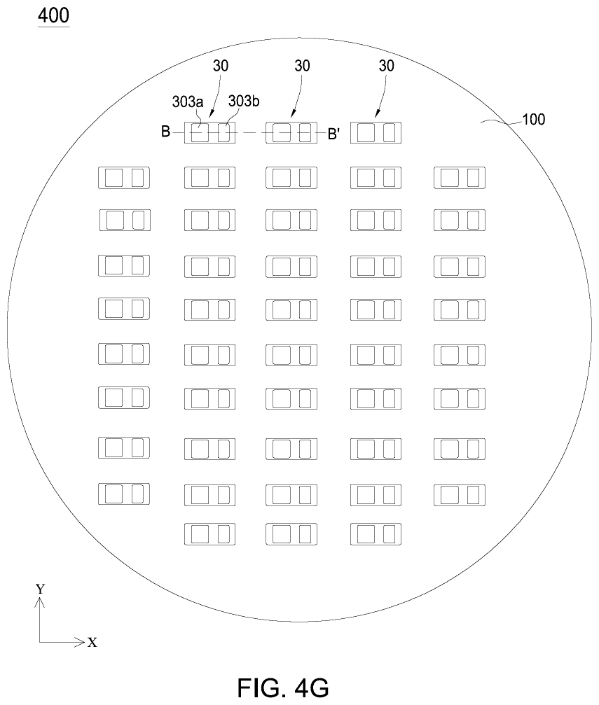

In this embodiment, the first semiconductor structure 110 does not include the first cladding layer 110a as shown in FIG. 1A, and the first semiconductor contact layer 110b serves as the thickest layer in the first semiconductor structure 110 and can provide carriers (such as electrons), structural support, current diffusion and contact characteristics needed. Since the first semiconductor contact layer 110b can have multiple functions including providing carriers and forming ohmic contact with the first contact electrode 201, the device structure can be further simplified. On the other hand, in the producing process of the semiconductor device 30 of this embodiment (the embodiments of FIG. 4A to FIG. 4G described later can be referred to), there is no need to transfer the substrate (for example, bonding the epitaxial structure 10 to a bonding substrate and removing the growth substrate) before forming the first electrode pad 303a and the second electrode pad 303b, thus can further simplify the device producing process and help to reduce production costs. The detailed descriptions of positions, relative relationships and material of other layers or structures as well as structural variations in this embodiment can be referred to the foregoing embodiments and are not repeatedly described herein.

FIG. 4A to FIG. 4F show schematic views of a method for producing a semiconductor component 400 in accordance with an embodiment of the present disclosure. The semiconductor component 400 may include a semiconductor device (such as the semiconductor device 20A, 20B, 20C, or 30) as described in any embodiment of the present disclosure. In this embodiment, a method for producing a semiconductor component 400 including a plurality of semiconductor devices 30 is taken as an example for description.

First, referring to FIG. 4A, the base 100 is provided, and an epitaxial growth is performed on the base 100 to form the epitaxial structure 10. The base 100 is a growth substrate (such as a GaAs substrate) for epitaxial growth. Then, a conductive oxide layer 301 can optionally be formed on the epitaxial structure 10. As shown in FIG. 4A, the conductive oxide layer 301 can cover the entire upper surface of the epitaxial structure 10.

Referring to FIG. 4B, next, a first etching process is performed to remove a portion of the epitaxial structure 10 so as to form a plurality of recesses 10C and a plurality of trenches 10D in the epitaxial structure 10. Here, removing a portion of the epitaxial structure 10 includes removing a portion of the first semiconductor structure 110, a portion of the second semiconductor structure 120, and a portion of the active region 130. During the first etching process, a portion of the conductive oxide layer 301 may be removed at the same time. As shown in FIG. 4B, each recess 10C may have a first width W1, and each trench 10D may have a second width W2 that is greater than the first width W1. In an embodiment, a thickness t1 of the removed portion of the epitaxial structure 10 may account for 20% to 40% of the total thickness of the epitaxial structure 10, such that a portion of the first semiconductor contact layer 110b in the first semiconductor structure 110 can be exposed. Through the first etching process, a plurality of first mesa structures M1 and a plurality of second mesa structures M2 that are alternately arranged can be defined in the epitaxial structure 10. The thicknesses of the first mesa structure M1 and the second mesa structure M2 are the thickness t1. The adjacent first mesa structure M1 and second mesa structure M2 are separated by a recess 10C or a trench 10D. Each first mesa structure M1 may have a third width W3, and each second mesa structure M2 may have a fourth width W4 smaller than the third width W3. The first etching process may include dry etching or wet etching process. The dry etching process is, for example, electron cyclotron resonance (ECR), inductively coupled plasma (ICP) or reactive ion etching (RIE).

Then, as shown in FIG. 4C, the first contact electrode 201 in direct contact with the first semiconductor contact layer 110b is formed in each recess 10C, and the second contact electrode 202 in direct contact with the conductive oxide layer 301 is formed on each first mesa structure M1. In absence of the conductive oxide layer 301 on the epitaxial structure 10, the second contact electrode 202 may be in direct contact with the second semiconductor contact layer 120b. In detail, the first contact electrode 201 and the second contact electrode 202 can be formed by sputtering or evaporation. After the first contact electrode 201 and/or the second contact electrode 202 are formed, a heat treatment may be performed to form good electrical contact (such as ohmic contact) between the first contact electrode 201 and the first semiconductor contact layer 110b, and the second contact electrode 202 and the conductive oxide layer 301 (or the second semiconductor contact layer 120b). The heat treatment is performed in a furnace, for example.

Then, as shown in FIG. 4D, a second etching process can be performed to remove a portion of the first semiconductor structure 110 in the trench 10D, so as to define a plurality of semiconductor devices 30 (as an example, FIG. 4D shows two semiconductor devices), each semiconductor device 30 includes a first mesa structure M1 and a second mesa structure M2. In detail, in this embodiment, in the second etching process, the first semiconductor contact layer 110b in the first semiconductor structure 110 can be removed, and an isolation region R in the trench 10D can be further formed. In accordance with an embodiment, the etching stop layer 110c outside the defined range of the semiconductor devices 30 (i.e., the isolation region R) can be completely or partially removed after the second etching process. The second etching process may include dry etching or wet etching.

Referring to FIG. 4E, an insulating structure 302 can be formed on the epitaxial structure 10. The method of forming the insulating structure 302 is, for example, chemical vapor deposition (CVD) such as plasma enhanced chemical vapor deposition (PECVD). In this embodiment, the insulating structure 302 covers the conductive oxide layer 301 and the second semiconductor contact layer 120b, and may cover side surfaces of every layer in the second semiconductor structure 120 and every layer in the active region 130. In accordance with an embodiment, the insulating structure 302 may further cover a surface of the first semiconductor contact layer 110b that constitutes a portion of the recess 10C (such as the portion indicated by arrow A0 in FIG. 4E) to ensure insulation effect. The insulation structure 302 may have a plurality of first openings 302s1 and a plurality of second openings 302s2. As shown in FIG. 4E, the first openings 302s1 overlaps with the first contact electrode 201 in a vertical direction (such as Z direction), and the second openings 302s2 overlaps with the second contact electrode 202 in the vertical direction (such as Z direction). A width of the first opening 302s1 can be less than or equal to the corresponding width of the first contact electrode 201, and a width of the second opening 302s2 can be less than or equal to the corresponding width of the second contact electrode 202 so as to ensure that the electrode pads are electrically connected to the epitaxial structure 10 via the first contact electrode 201 and the second contact electrode 202 when the device operates.

As shown in FIG. 4E, the insulation structure 302 may have a plurality of third openings 302S3. The third opening 302S3 overlaps with the trench 10D (or the isolation region R) in the vertical direction (such as Z direction). The first opening 302s1, the second opening 302s2 and the third opening 302S3 may be formed by performing an etching process after depositing the material of the insulating structure 302, or the insulation structure 302 having the first opening 302s1, the second opening 302s2 and the third opening 302S3 may be directly formed through a photomask. The etching process can include dry etching or wet etching.

Next, referring to FIG. 4F and FIG. 4G, the first electrode pad 303a and the second electrode pad 303b are respectively formed on the first contact electrode 201 and the second contact electrode 202, so as to form the semiconductor component 400. The first electrode pad 303a fills the first opening 302s1 and directly contacts the upper surface 201a of the first contact electrode 201 to form an electrical connection. The second electrode pad 303b fills the second opening 302s2 and directly contacts the upper surface 202a of the second contact electrode 202 to form an electrical connection. The first electrode pad 303a and the second electrode pad 303b can be formed by sputtering or evaporation. As shown in FIG. 4G, after forming the first electrode pad 303a and the second electrode pad 303b, when viewed from above, the semiconductor component 400 includes a plurality of semiconductor devices 30. The plurality of semiconductor devices 30 is arranged in a two-dimensional array along the first direction (X direction) and the second direction (Y direction). Specifically, the cross-sectional structure as shown in FIG. 4F is, for example, the cross-sectional view along line B-B′ in FIG. 4G.

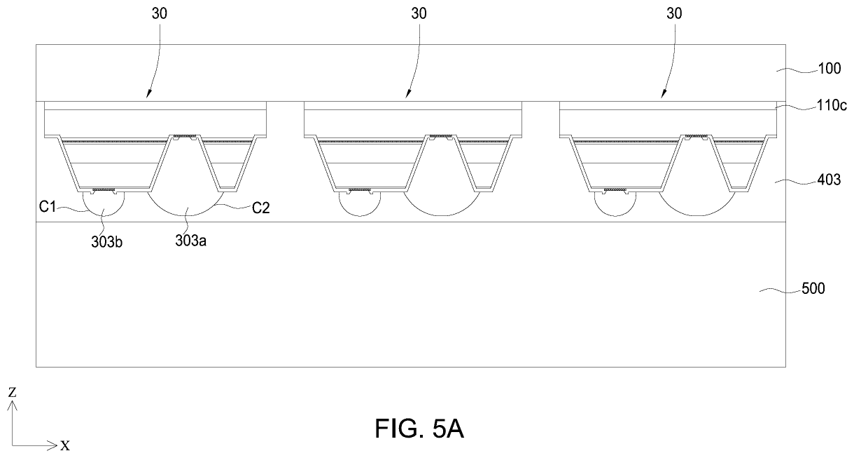

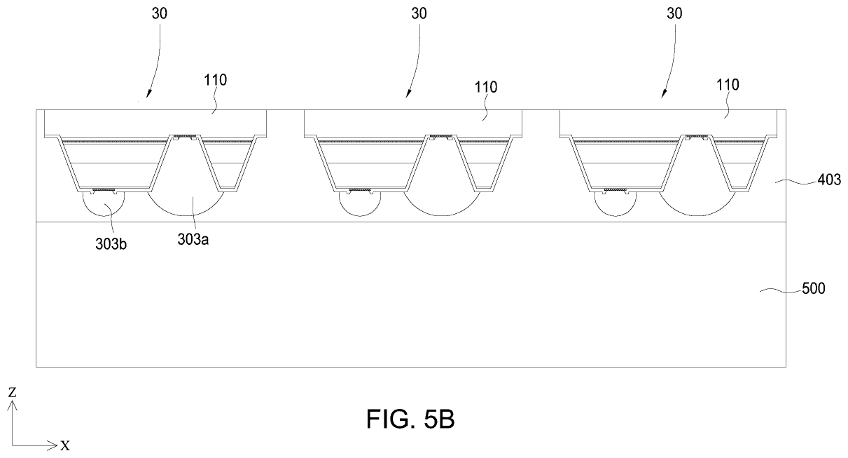

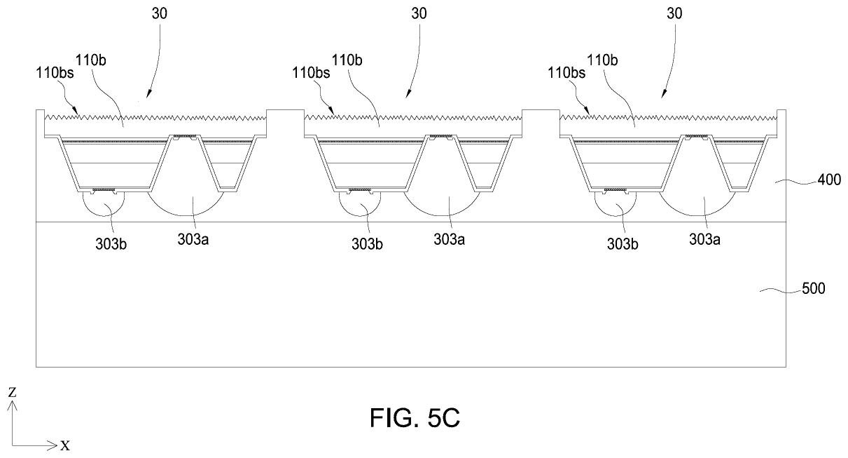

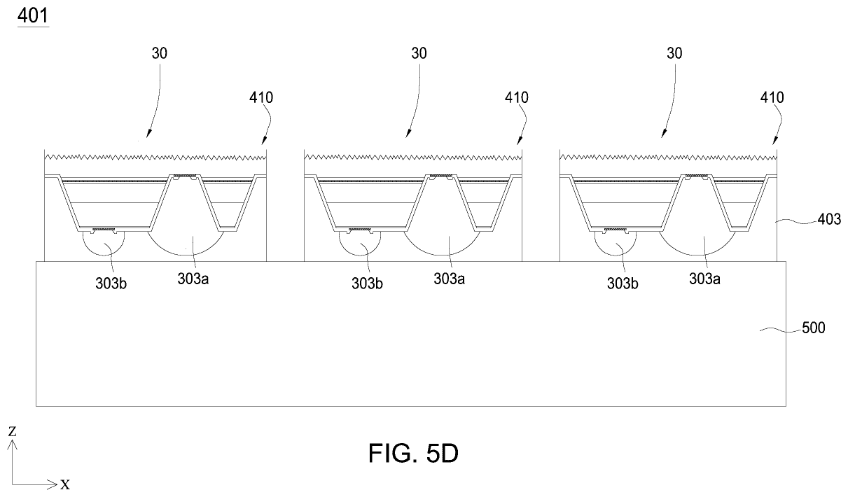

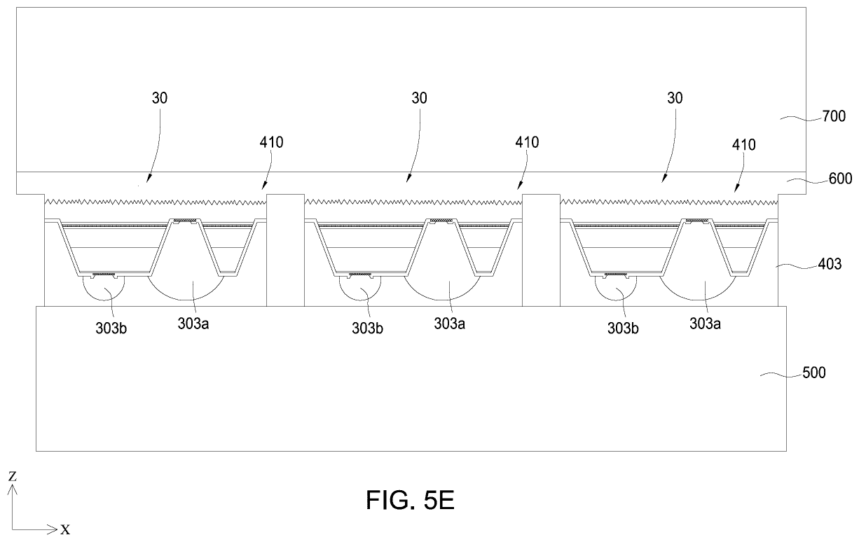

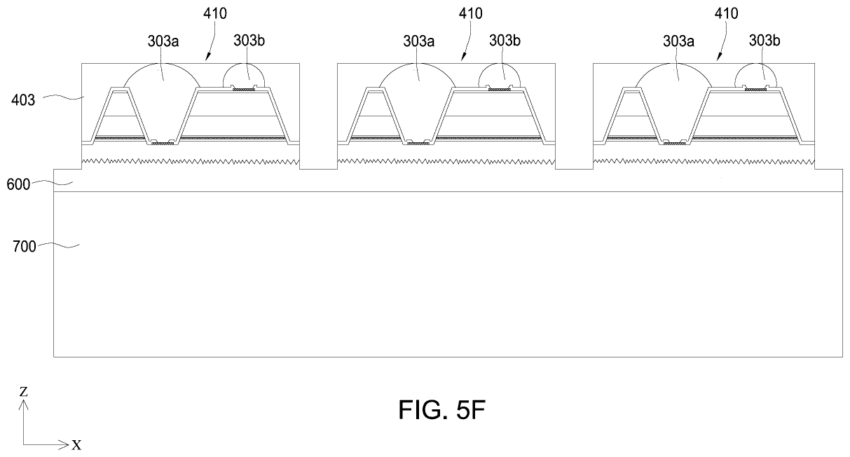

FIG. 5A to FIG. 5F show schematic views of a method for producing a semiconductor component 401 in accordance with an embodiment of the present disclosure. The method for producing the semiconductor component 401 may optionally include the steps shown in FIG. 5A to FIG. 5D. Specifically, as shown in FIG. 4F and FIG. 4G, after forming the first electrode pad 303a and the second electrode pad 303b, the plurality of semiconductor devices 30 on the base 100 can be further bonded to a temporary substrate 500 through the adhesive layer 403, and can be flipped upside down to form a structure as shown in FIG. 5A (as an example, FIG. 5A shows three semiconductor devices). The temporary substrate 500 can provide structural support and is, for example, a silicon (Si) substrate or a sapphire substrate. The plurality of semiconductor devices 30 may be embedded in the adhesive layer 403. The adhesive layer 403 may surround each semiconductor device 30 and be distributed between adjacent semiconductor devices 30 and between the first electrode pad 303a and the second electrode pad 303b in each semiconductor device 30. As shown in FIG. 5A, in each semiconductor device 30, except for the surface facing the base 100, other surfaces of each semiconductor device 30 are all in direct contact with the adhesive layer 403. The adhesive layer 403 may include a thermal release tape, UV release tape, chemical release tape, heat resistant tape, blue tape, or a tape with dielectric release layer (DRL). The material of the adhesive layer 403 is, for example, an insulating adhesive, which may include polyimide, benzocyclobutene (BCB), epoxy resin, silicone resin, acrylic resin, polyester, or a combination thereof. As shown in FIG. 5A, the first electrode pad 303a and the second electrode pad 303b in the semiconductor device 30 can be fixed in the adhesive layer 403 in a downward direction so the first electrode pad 303a and the second electrode pad 303b can face the temporary substrate 500. Since the plurality of semiconductor devices 30 is temporarily fixed in the adhesive layer 403 by being embedded in the adhesive layer 403, the relative positions between the plurality of semiconductor devices 30 can be maintained.

The first electrode pad 303a and the second electrode pad 303b may be separated from the temporary substrate 500 by a distance, or may directly contact the temporary substrate 500 (not shown). In accordance with an embodiment, if the first electrode pad 303a and the second electrode pad 303b are separated from the temporary substrate 500 by the distance, the first electrode pad 303a and the second electrode pad 303b can be prevented from being squeezed and damaged. In this embodiment, the first electrode pad 303a and the second electrode pad 303b protrude from a side near the epitaxial structure 10 toward the temporary substrate 500. The cross-sectional profile of the second electrode pad 303b may have a first arc portion C1, and the first electrode pad 303a may have a second arc portion C2. The design can increase surface areas of the electrode pads, thus contributing to the stability of the bonding and also help to further improve the reliability of physical and electrical connections in subsequent fixation of the semiconductor devices 30 to a carrier board (such as a circuit substrate).

Then, as shown in FIG. 5B, the base 100 can be removed to expose the first semiconductor structure 110. In this embodiment, the etching stop layer 110c in the first semiconductor structure 110 can be completely removed and leaving the first semiconductor contact layer 110b exposed.

Next, as shown in FIG. 5C, optionally, a roughening process can be further performed on an exposed surface of the first semiconductor structure 110 to form a roughened structure 110bs (here the exposed surface is a surface of the first semiconductor contact layer 110b). By having a roughened structure 110bs on the surface of the first semiconductor structure 110, the light extraction efficiency of the semiconductor device 30 can be improved. The methods of removing the base 100 and/or the etching stop layer 110c and the roughening process can be, for example, dry etching or wet etching.

Next, as shown in FIG. 5D, a portion of the adhesive layer 403 (for example, the parts distributed between adjacent semiconductor devices 30) can be further removed, so that spatially independent units 410 can be formed by each semiconductor device 30 and a remaining portion of the adhesive layer 403 surrounding each semiconductor device 30. Specifically, the plurality of units 410 can be formed by removing portions of the adhesive layer 403 that do not overlap with the semiconductor device 30 in the vertical direction (Z direction) by dry etching or wet etching. In some embodiments, the adhesive layer 403 can serve as a release layer, for example, the temporary substrate 500 and the structures on the temporary substrate 500 can be separated by further etching, laser stripping, heating or UV light treatment on the adhesive layer 403. In each unit 410 shown in FIG. 5D, the first electrode pad 303a and the second electrode pad 303b of the semiconductor device 30 face downward, that is, the first electrode pad 303a (or the second electrode pad 303b) is located between the epitaxial structure 10 and the temporary substrate 500. Since the units 410 are spatially independent, subsequent steps such as transfer or other process can be performed according to actual needs for facilitating process operability.

The method for producing the semiconductor component 401 may optionally include steps shown in FIG. 5E to FIG. 5F. Specifically, as shown in FIG. 5E, the plurality of units 410 on the temporary substrate 500 can be further fixed to a target substrate 700 through a connection layer 600. The connection layer 600 may include a transparent adhesive material. According to some embodiments, the target substrate 700 may be a circuit board or a TFT substrate for display, a submount of a package, or a temporary carrier similar to the temporary substrate 500. Then, the connected structure can be flipped upside down and the temporary substrate 500 can be removed to obtain a structure as shown in FIG. 5F. For example, the temporary substrate 500 can be removed by wet etching or dry etching.

In each unit 410 shown in FIG. 5F, the first electrode pad 303a and the second electrode pad 303b of the semiconductor device 30 are facing upward, and the epitaxial structure 10 is located between the first electrode pad 303a (or the second electrode pad 303b) and the target substrate 700. In accordance with an embodiment, the adhesive layer 403 in each unit 410 may be further removed. For example, the adhesive layer 403 covering each semiconductor device 30 can be completely or partially removed by wet etching or dry etching. In accordance with an embodiment, when the target substrate 700 serve as a temporary carrier, the connection layer 600 can be used as a release layer, for example, by further etching, laser stripping, heating or UV light treatment on the connection layer 600, each unit 410 can be separated from the target substrate 700.

In accordance with another embodiment, in each unit 410, the adhesive layer 403 distributed near the first electrode pad 303a and the second electrode pad 303b can be removed, so that surfaces of the first electrode pad 303a and the second electrode pad 303b can be exposed, and a redistribution layer (RDL) can be further formed on the semiconductor devices 30 to form an electrical connection structure needed.

In accordance with another embodiment, the plurality of units 410 can be fixed to the target substrate 700 in a manner that the first electrode pad 303a and the second electrode pad 303b in each unit 410 face downward, that is, the first electrode pad 303a (or the second electrode pad 303b) is located between the epitaxial structure 10 and the target substrate 700. Specifically, after obtaining the structure shown in FIG. 5D, the semiconductor devices 30 on the temporary substrate 500 can be further bonded to another temporary substrate (not shown, the material thereof can refer to the material of the temporary substrate 500) through another adhesive layer (not shown, the material thereof can refer to the material of the adhesive layer 403). The bonded structure can be flipped upside down and the temporary substrate 500 can be removed, then the units 410 can be fixed to the target substrate 700 and another temporary substrate can be further removed, so as to form a plurality of units 410 in which the first electrode pad 303a and the second electrode pad 303b are located between the epitaxial structure 10 and the target substrate 700.

It can be seen from the embodiments shown in FIG. 4A to FIG. 5F that the semiconductor component 400 including the semiconductor devices 30 can have different structural configurations, and can be selected based on actual needs. Specifically, in the producing process of the semiconductor component 400, no substrate transfer is needed before forming the first electrode pad 303a and the second electrode pad 303b (for example, bonding the epitaxial structure 10 to the bonding substrate and removing the growth substrate), thus there is no need to consider the tolerance of the material of the bonding structure 230 to conditions of the heat treatment, such as temperature or other parameters, thereby improving the process yield, further simplifying the device producing process, and helping to reduce production costs. The detailed descriptions of positions, relative relationships and material of other layers or structures as well as structural variations in this embodiment can be referred to the foregoing embodiments and are not repeatedly described herein.

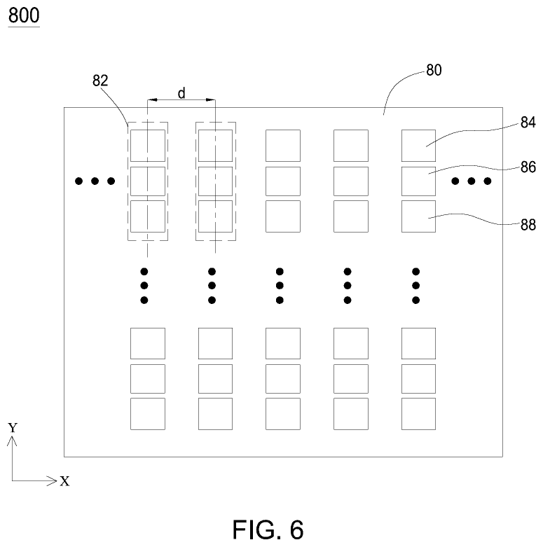

FIG. 6 shows a schematic sectional view of a semiconductor component 800 in accordance with an embodiment of the present disclosure. The semiconductor component 800 of the embodiment is, for example, a display. As shown in FIG. 6, the semiconductor component 800 includes a carrier board 80 and a plurality of pixel units 82 on the carrier board 80. The pixel units 82 are arranged in an array along the directions parallel to the x-axis and the y-axis, and are arranged at an interval d in the direction parallel to the x-axis. The number of pixel units 82 can be adjusted based on actual needs. For example, in an embodiment, a display with a resolution of 1920×1080 pixels can be provided by the plurality of pixel units 82 included in the semiconductor component 800. In an embodiment, the interval d is less than 1.4 mm, for example, and the interval d is in a range of 0.2 mm to 1.3 mm, such as 0.75 mm, 0.8 mm, 1 mm or 1.25 mm. As shown in FIG. 6, each pixel unit 82 includes a first semiconductor device 84, a second semiconductor device 86, and a third semiconductor device 88 arranged in a direction parallel to the y-axis. One or more of the first semiconductor device 84, the second semiconductor device 86, and the third semiconductor device 88 is the semiconductor device described in any embodiment of the present disclosure, such as the semiconductor device 20A, 20B, 20C or 30. In an embodiment, the first semiconductor device 84, the second semiconductor device 86, and the third semiconductor device 88 are all light-emitting devices and can emit red light, green light, and blue light, respectively. In an embodiment, the arrangement order of the light-emitting devices can also be adjusted based on actual needs. For example, the first semiconductor device 84, the second semiconductor device 86, and the third semiconductor device 88 emit red light, blue light, and green light, respectively. Each pixel unit 82 can be electrically connected to a circuit (not shown) on the surface of the carrier board 80, so that the light-emitting devices therein can receive an external signal and emit light in accordance with the external signal. The carrier board 80 may have a single-layer or multi-layer structure. In an embodiment, the material of the carrier board 80 includes a polyester, polyimide (PI), BT (Bismaleimide Triazine) resin, PTFE (Polytetrafluoroethylene) resin, phenol resin (PF) or glass fiber epoxy resin (such as FR4). In an embodiment, the carrier board 80 can be bent, and for example, can withstand a radius of curvature less than 50 mm, such as 25 mm or 32 mm.

Based on the above, an epitaxial structure, a semiconductor device and a producing method thereof, a semiconductor component including the same or a method for producing the semiconductor component can be provided in the present disclosure. For example, contact characteristics can be improved, the device producing process can be simplified, production costs can be reduced, and/or the process stability or production yield can be elevated. The description provided in the present disclosure is also suitable for applying on semiconductor devices with miniaturization needs, and can be widely used in various fields. Specifically, the epitaxial structure, the semiconductor device and the semiconductor component of the present disclosure can be applied to products in various fields, such as illumination, display, communication or power supply system, for example, can be used in a light fixture, monitor, an automotive instrument panel, a television, computer, traffic sign, or an outdoor display device.

It should be realized that each of the embodiments mentioned in the present disclosure is used for describing the present disclosure, but not for limiting the scope of the present disclosure. Any obvious modification or alteration is not departing from the spirit and scope of the present disclosure. Furthermore, embodiments may be combined or substituted under proper condition and are not limited to specific embodiments described above. A connection relationship between a specific component and another component specifically described in an embodiment can also be applied in another embodiment and is within the scope as claimed in the present disclosure.

What is claimed is:

1. A semiconductor device, comprising:
an epitaxial structure, comprising:
a first semiconductor structure comprising a first semiconductor contact layer;
a second semiconductor structure comprising a second semiconductor contact layer; and
an active region located between the first semiconductor structure and the second semiconductor structure;
a first contact electrode located on the second semiconductor contact layer and directly contacting the first semiconductor contact layer; and
a second contact electrode located on the second semiconductor contact layer and directly contacting the second semiconductor contact layer;
wherein the first semiconductor contact layer has a conductivity type of n-type and comprises a first group III-V semiconductor material, the second semiconductor contact layer has a conductivity type of p-type and comprises a second group III-V semiconductor material, and the second group III-V semiconductor material is an indium-containing phosphide.

2. The semiconductor device of claim 1, wherein the second group III-V semiconductor material has an indium content in a range of 1% to 30%.

3. The semiconductor device of claim 1, wherein the first group III-V semiconductor material and the second group III-V semiconductor material are different.

4. The semiconductor device of claim 3, wherein the first group III-V semiconductor material is a binary group III-V compound semiconductor, and the second group III-V semiconductor material is a ternary group III-V compound semiconductor.

5. The semiconductor device of claim 4, wherein the ternary group III-V compound semiconductor is InₓGa₁₋ₓP, wherein 0<x<1.

6. The semiconductor device of claim 5, wherein x is in a range of 0.05 to 0.3.

7. The semiconductor device of claim 4, wherein the binary group III-V compound semiconductor is GaAs.

8. The semiconductor device of claim 1, wherein the first semiconductor contact layer has a first thickness, and the second semiconductor contact layer has a second thickness greater than the first thickness.

9. The semiconductor device of claim 1, wherein the active region comprises a first confinement layer, a second confinement layer and a light-emitting region located between the first confinement layer and the second confinement layer.

10. The semiconductor device of claim 1, wherein the first semiconductor contact layer or the second semiconductor contact layer has a first side away from the active region and a second side closer to the active region than the first side, and a dopant concentration on the first side is higher than that on the second side.

11. A semiconductor device, comprising:
an epitaxial structure, comprising:
a first semiconductor structure comprising a first semiconductor contact layer;
a second semiconductor structure comprising a second semiconductor contact layer; and
an active region located between the first semiconductor structure and the second semiconductor structure;
a first contact electrode located on the first semiconductor contact layer and directly contacting the first semiconductor contact layer; and
a second contact electrode located on the first semiconductor contact layer and directly contacting the second semiconductor contact layer;
wherein the first semiconductor contact layer has a conductivity type of n-type and comprises a first group III-V semiconductor material, the second semiconductor contact layer has a conductivity type of p-type and comprises a second group III-V semiconductor material, the first group III-V semiconductor material is an indium-containing phosphide and is a ternary group III-V compound semiconductor.

12. The semiconductor device of claim 11, wherein the first semiconductor contact layer has a plurality of pairs of first sublayers and second sublayers which are alternately stacked, each of the first sublayers comprises the first group III-V semiconductor material, and each of the second sublayers comprises a third group III-V semiconductor material different from the first group III-V semiconductor material.

13. The semiconductor device of claim 12, wherein the first semiconductor contact layer comprises 2 pairs to 500 pairs of the first sublayers and the second sublayers.

14. The semiconductor device of claim 11, wherein the first group III-V semiconductor material is Al_{y}In_{1-y}P, wherein 0<y<1.

15. The semiconductor device of claim 11, wherein the second group III-V semiconductor material is a binary group III-V compound semiconductor.

16. The semiconductor device of claim 15, wherein the binary group III-V compound semiconductor is GaP.

17. The semiconductor device of claim 11, wherein the first semiconductor contact layer has a first thickness, the second semiconductor contact layer has a second thickness less than the first thickness.

18. The semiconductor device of claim 12, wherein the third group III-V semiconductor material is an indium-containing phosphide.

19. The semiconductor device of claim 11, wherein the first semiconductor contact layer or the second semiconductor contact layer has a first side away from the active region and a second side closer to the active region than the first side, and a dopant concentration on the first side is higher than that on the second side.

20. The semiconductor device of claim 17, wherein the first thickness and the second thickness are respectively in a range of 300 Å to 30000 Å.
